(19) United States
(12) Patent Application Publication
(10) Pub. No.: US 2021/0359662 A1
(43) Pub. Date: Nov. 18, 2021

(54) BULK-ACOUSTIC WAVE RESONATOR AND BULK-ACOUSTIC WAVE RESONATOR FABRICATION METHOD

(71) Applicant: Samsung Electro-Mechanics Co., Ltd., Suwon-si (KR)

(72) Inventors: Tae Kyung LEE, Suwon-si (KR); Yong Suk KIM, Suwon-si (KR); Sang Kee YOON, Suwon-si (KR); Chang Hyun LIM, Suwon-si (KR); Tae Hun LEE, Suwon-si (KR); Jin Woo YI, Suwon-si (KR)

(73) Assignee: Samsung Electro-Mechanics Co., Ltd., Suwon-si (KR)

(21) Appl. No.: 16/953,431

(22) Filed: Nov. 20, 2020

(30) Foreign Application Priority Data
May 13, 2020 (KR) 10-2020-0057211
Jul. 20, 2020 (KR) 10-2020-0089825

(51) Int. Cl. H03H 9/17; H03H 9/13; H03H 9/02; H03H 3/02; H01L 41/35

(52) U.S. Cl. CPC H03H 9/17; H03H 9/13; H01L 41/35; H03H 3/02; H03H 9/02007

(57) ABSTRACT

A bulk-acoustic wave resonator includes a resonator, including a first electrode, a piezoelectric layer, and a second electrode sequentially stacked on a substrate; and an insertion layer disposed below the piezoelectric layer, and configured to partially elevate the piezoelectric layer and the second electrode, wherein the insertion layer may be formed of a material containing silicon (Si), oxygen (O), and nitrogen (N).

### CROSS-REFERENCE TO RELATED APPLICATION(S)

This application claims the benefit under 35 USC § 119(a) of Korean Patent Application No. 10-2020-0057211, filed on May 13, 2020, and Korean Patent Application No. 10-2020-0089825, filed on Jul. 20, 2020 in the Korean Intellectual Property Office, the entire disclosures of which are incorporated herein by reference for all purposes.

### BACKGROUND

### 1. Field

The following description relates to a bulk-acoustic wave resonator, and a bulk acoustic wave fabrication method.

### 2. Description of Related Art

In accordance with the trend to miniaturize wireless communication devices, the miniaturization of high frequency component technology is in great demand. For example, a bulk-acoustic wave (BAW) type filter that uses semiconductor thin film wafer manufacturing technology may be implemented.

A bulk-acoustic resonator (BAW) is formed when a thin film type element, that causes resonance by depositing a piezoelectric dielectric material on a silicon wafer, a semiconductor substrate, and using the piezoelectric characteristics thereof, is implemented as a filter.

Recently, technological interest in 5G communications is increasing, and the development of technologies that can be implemented in candidate bands is being actively performed.

However, in the case of 5G communications implementing a Sub 6 GHz (4 to 6 GHz) frequency band, since the bandwidth is increased and the communication distance shortened, the strength or power of the signal of the bulk-acoustic wave resonator may be increased. Additionally, as the frequency increases, losses occurring in the piezoelectric layer or the resonator may be increased.

Therefore, a bulk-acoustic wave resonator that minimizes stable energy leakage may be beneficial in the resonator.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a bulk-acoustic wave resonator includes a resonator, comprising a first electrode, a piezoelectric layer, and a second electrode sequentially stacked on a substrate; and an insertion layer, disposed below the piezoelectric layer, and configured to partially elevate the piezoelectric layer and the second electrode, wherein the insertion layer is formed of a material containing silicon (Si), oxygen (O), and nitrogen (N).

An at % content of the nitrogen (N) contained in the insertion layer may be 0.86% or higher than the at % content of the entire insertion layer, and is lower than an at % content of oxygen (O).

The piezoelectric layer may be formed of one of aluminum nitride (AlN) and scandium (Sc) doped aluminum nitride.

The first electrode may be formed of molybdenum (Mo).

The insertion layer may be formed of a material having an acoustic impedance lower than an acoustic impedance of the first electrode and the piezoelectric layer.

The resonator may include a central portion disposed in a central region, and an extension portion disposed at a periphery of the central portion, the insertion layer may be disposed in the extension portion of the resonator, the insertion layer may have an inclined surface of which a thickness increases as a distance from the central portion increases, and the piezoelectric layer comprises an inclined portion disposed on the inclined surface of the insertion layer.

In a cross-section cut across the resonator, an end of the second electrode may be disposed at a boundary between the central portion and the extension portion, or disposed on the inclined portion.

The piezoelectric layer may include a piezoelectric portion disposed in the central potion, and an extension portion extending outwardly of the inclined portion, and at least a portion of the second electrode may be disposed on the extension portion of the piezoelectric layer.

In a general aspect, a bulk-acoustic wave resonator manufacturing method includes forming a resonator, in which a first electrode, a piezoelectric layer, and a second electrode are sequentially stacked, wherein the forming of the resonator includes forming an insertion layer below the first electrode, or forming the insertion layer between the first electrode and the piezoelectric layer to partially elevate the piezoelectric layer and the second electrode, and wherein the insertion layer is formed of a material containing silicon (Si), oxygen (O), and nitrogen (N).

An at % content of the nitrogen (N) contained in the insertion layer may be 0.86% or higher than the at % content of the entire insertion layer and may be lower than an at % content of oxygen (O).

The insertion layer may be formed by mixing SiH₄, and N₂O gases in a predetermined ratio.

The insertion layer may be formed by a chemical vapor deposition (CVD) method, and by applying the following equation: SiH₄+N₂O→H₂.

The insertion layer may be formed by mixing SiH₄, O₂, and N₂ gases in a predetermined ratio.

The insertion layer may be formed by a chemical vapor deposition (CVD) method, and following by applying the following equation: SiH₄+O₂+N₂→H₂.

The insertion layer may be formed of one of aluminum nitride (AlN) and scandium (Sc) doped aluminum nitride.

The insertion layer may be formed of a material having an acoustic impedance that is lower than an acoustic impedance of the first electrode and the piezoelectric layer.

In a general aspect, a bulk-acoustic wave resonator includes a substrate; a resonator, including a central portion including a first electrode, a piezoelectric layer, and a second electrode sequentially stacked on the substrate, and an extension portion, extending from the central portion, and including an insertion layer disposed between the first electrode and the piezoelectric layer; wherein the insertion layer is formed of a silicon dioxide (SiO₂) thin film.

Nitrogen (N) may be injected into the SiO₂ thin film.

Other features and aspects will be apparent from the following detailed description, the drawings, and the claims.

### BRIEF DESCRIPTION OF DRAWINGS

FIG. 1 illustrates a plan view of a bulk-acoustic wave resonator, in accordance with one or more embodiments.

FIG. 2 illustrates a cross-sectional view taken along line I-I′ of FIG. 1.

FIG. 3 illustrates a cross-sectional view taken along line II-II′ of FIG. 1.

FIG. 4 illustrates a cross-sectional view taken along line III-III′ in FIG. 1.

FIGS. 5 and 6 are views illustrating critical dimensions of a bulk-acoustic wave resonator, in which an insertion layer is formed of a silicon dioxide material, in accordance with one or more embodiments.

FIGS. 7 and 8 are views illustrating critical dimensions of a bulk-acoustic wave resonator, in which an insertion layer is formed of a silicon dioxide material, in accordance with one or more embodiments.

FIGS. 9 and 10 are views illustrating critical dimensions of a bulk-acoustic wave resonator, in which an insertion layer is formed of a SiOxNy material, in accordance with one or more embodiments.

FIGS. 11 and 12 are views illustrating critical dimensions of a bulk-acoustic wave resonator, in which an insertion layer is formed of a SiOxNy material, in accordance with one or more embodiments.

FIGS. 13 and 14 are views illustrating critical dimensions of a bulk-acoustic wave resonator, in which an insertion layer is formed of a SiOxNy material, in accordance with one or more embodiments.

FIGS. 15 and 16 are views illustrating critical dimensions of a bulk-acoustic wave resonator, in which an insertion layer is formed of a SiOxNy material, in accordance with one or more embodiments.

FIG. 17 is a schematic cross-sectional view of a bulk-acoustic wave resonator, in accordance with one or more embodiments. and

FIG. 18 is a schematic cross-sectional view of a bulk-acoustic wave resonator, in accordance with one or more embodiments.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms, including technical and scientific terms, used herein have the same meaning as commonly understood by one of ordinary skill in the art to which this disclosure pertains and after an understanding of the disclosure of this application. Terms, such as those defined in commonly used dictionaries, are to be interpreted as having a meaning that is consistent with their meaning in the context of the relevant art and the disclosure of this application, and are not to be interpreted in an idealized or overly formal sense unless expressly so defined herein.

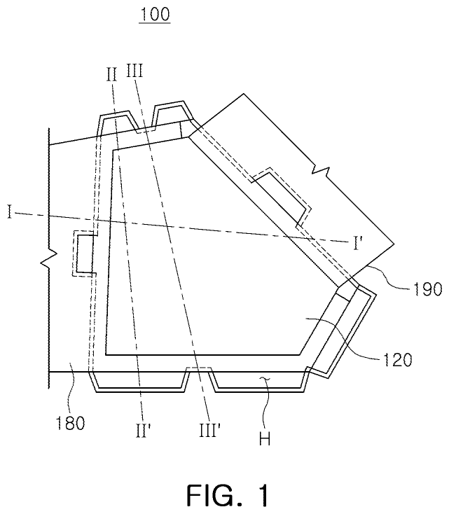

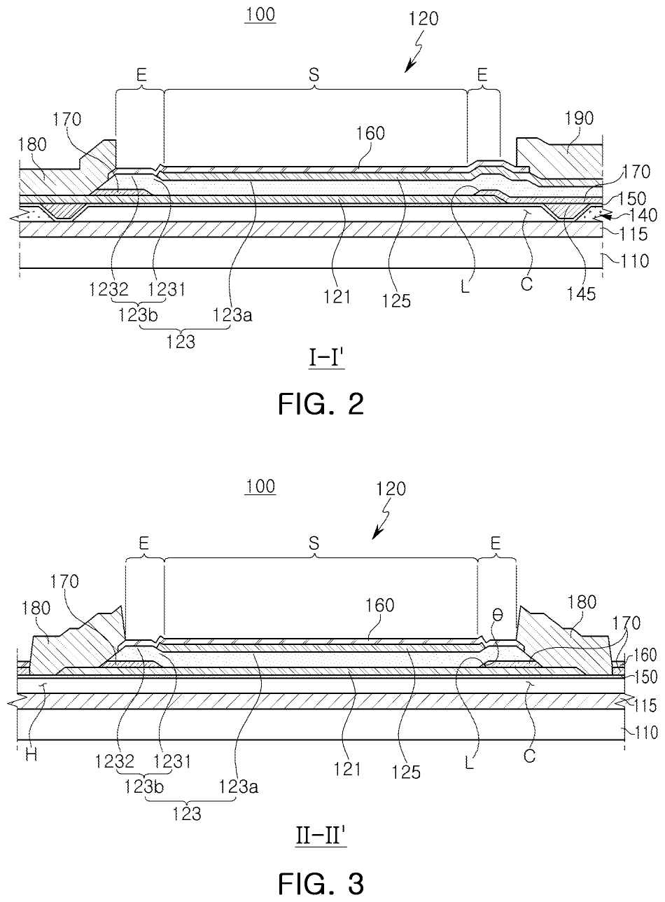

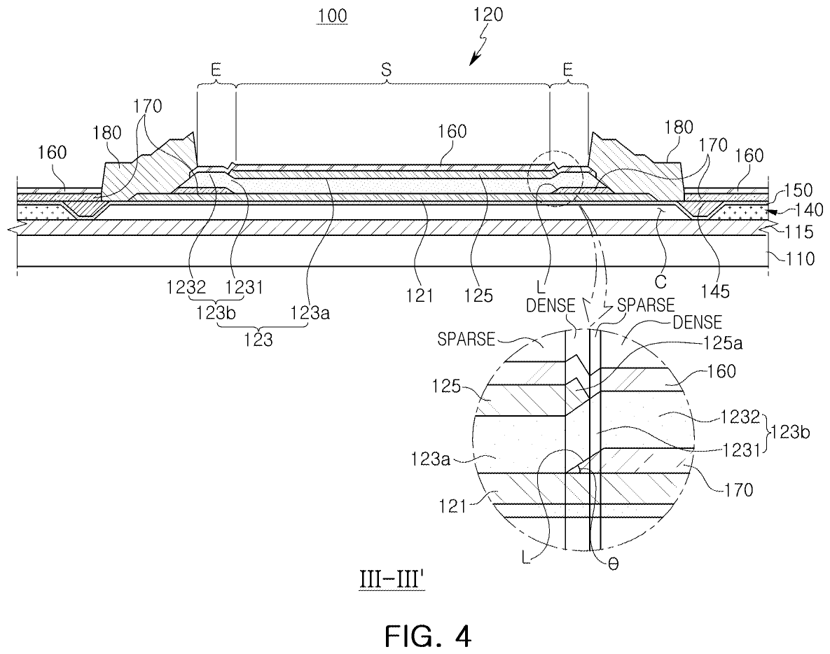

FIG. 1 illustrates a plan view of an acoustic wave resonator, in accordance with one or more embodiments, FIG. 2 illustrates a cross-sectional view taken along line I-I′ of FIG. 1, FIG. 3 illustrates a cross-sectional view taken along line II-II′ of FIG. 1, and FIG. 4 illustrates a cross-sectional view taken along line III-III′ of FIG. 1.

Referring to FIGS. 1 to 4, an acoustic wave resonator 100, in accordance with one or more embodiments, may be a bulk-acoustic wave (BAW) resonator, and may include a substrate 110, a sacrificial layer 140, a resonator 120, and an insertion layer 170.

The substrate 110 may be a silicon substrate. In an example, a silicon wafer may be used as the substrate 110, or a silicon on insulator (SOI) type substrate may be used.

An insulating layer 115 may be provided on an upper surface of the substrate 110 to electrically isolate the substrate 110 and the resonator 120. Additionally, the insulating layer 115 may prevent the substrate 110 from being etched by an etching gas when a cavity C is formed in a manufacturing process of the acoustic-wave resonator.

In this example, the insulating layer 115 may be formed of at least one of, but not limited to, silicon dioxide (SiO₂), silicon nitride (Si₃N₄), aluminum oxide (Al₂O₃), and aluminum nitride (AlN), and may be formed through any one process of, but not limited to, chemical vapor deposition, RF magnetron sputtering, and evaporation.

A sacrificial layer 140 may be formed on the insulating layer 115, and the cavity C and an etch stop portion 145 may be disposed in the sacrificial layer 140.

The cavity C is formed as an empty space, and may be formed by removing a portion of the sacrificial layer 140.

As the cavity C may be formed in the sacrificial layer 140, the resonator 120 formed above the sacrificial layer 140 may be formed to be entirely flat.

The etch stop portion 145 may be disposed along a boundary of the cavity C. The etch stop portion 145 is provided to prevent etching from being performed beyond a cavity region in a process of forming the cavity C.

A membrane layer 150 may be formed on the sacrificial layer 140, and forms an upper surface of the cavity C. Therefore, the membrane layer 150 may also be formed of a material that is not easily removed in the process of forming the cavity C.

In an example, when a halide-based etching gas such as fluorine (F), chlorine (Cl), or the like is used to remove a portion (e.g., a cavity region) of the sacrificial layer 140, the membrane layer 150 may be made of a material having low reactivity with the etching gas. In this case, the membrane layer 150 may include at least one of silicon dioxide (SiO₂) and silicon nitride (Si₃N₄).

Additionally, the membrane layer 150 may be made of a dielectric layer containing at least one material of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or a metal layer containing at least one material of aluminum (Al), nickel (Ni), chromium (Cr), platinum (Pt), gallium (Ga), and hafnium (Hf). However, a configuration of the xamples is not limited thereto.

The resonator 120 may include a first electrode 121, a piezoelectric layer 123, and a second electrode 125. The resonator 120 is configured such that the first electrode 121, the piezoelectric layer 123, and the second electrode 125 are stacked in order from a bottom to a top location. Therefore, the piezoelectric layer 123 in the resonator 120 is disposed between the first electrode 121 and the second electrode 125.

Since the resonator 120 is formed on the membrane layer 150, the membrane layer 150, the first electrode 121, the piezoelectric layer 123, and the second electrode 125 are sequentially stacked on the substrate 110, to form the resonator 120.

The resonator 120 may resonate the piezoelectric layer 123 based on signals applied to the first electrode 121 and the second electrode 125 to generate a resonant frequency and an anti-resonant frequency.

The resonator 120 may be divided into a central portion S in which the first electrode 121, the piezoelectric layer 123, and the second electrode 125 are stacked to be substantially flat, and an extension portion E in which an insertion layer 170 is interposed between the first electrode 121 and the piezoelectric layer 123.

The central portion S is a region disposed in a central area of the resonator 120, and the extension portion E is a region disposed along a periphery of the central portion S. Therefore, the extension portion E is a region that externally extends from the central portion S, and is a region that is formed to have a continuous annular shape along the periphery of the central portion S. However, if necessary, the extension portion E may be configured to have a discontinuous annular shape, in which some regions are disconnected.

Accordingly, as shown in FIG. 2, in the cross-section of the resonator 120, which is cut to cross the central portion S, the extension portion E is disposed on both ends of the central portion S, respectively. An insertion layer 170 is disposed on both sides of the central portion S of the extension portion E disposed on both ends of the central portion S.

The insertion layer 170 has an inclined surface L of which a thickness increases as a distance from the central portion S of the resonator increases.

In the extension portion E, the piezoelectric layer 123 and the second electrode 125 are disposed on the insertion layer 170. Therefore, the portions of the piezoelectric layer 123 and the second electrode 125 that are located in the extension portion E, may have an inclined surface along the shape of the insertion layer 170.

In an example, the extension portion E may be included in the resonator 120, and accordingly, resonance may also occur in the extension portion E. However, the example is not limited thereto, and resonance may not occur in the extension portion E depending on the structure of the extension portion E, and resonance may only occur in the central portion S.

In a non-limiting example, the first electrode 121 and the second electrode 125 may be formed of a conductor, for example, gold, molybdenum, ruthenium, iridium, aluminum, platinum, titanium, tungsten, palladium, tantalum, chromium, nickel, or a metal containing at least one thereof, but is not limited thereto.

In the resonator 120, the first electrode 121 may be formed to have a larger area than the second electrode 125, and a first metal layer 180 may be disposed along a periphery of the first electrode 121 on the first electrode 121. Therefore, the first metal layer 180 may be disposed to be spaced apart from the second electrode 125 by a predetermined distance, and may be disposed in a form surrounding the resonator 120.

Since the first electrode 121 is disposed on the membrane layer 150, the first electrode 121 may be formed to be entirely flat. On the other hand, since the second electrode 125 is disposed on the piezoelectric layer 123, curving may be formed corresponding to the shape of the piezoelectric layer 123.

The first electrode 121 may be implemented as any one of an input electrode and an output electrode for inputting and outputting an electrical signal such as a radio frequency (RF) signal.

The second electrode 125 may be entirely disposed in the central portion S, and may be partially disposed in the extension portion E. Accordingly, the second electrode 125 may be divided into a portion disposed on a piezoelectric portion 123a of the piezoelectric layer 123 to be described later, and a portion disposed on a curved portion 123b of the piezoelectric layer 123.

More specifically, in the example, the second electrode 125 is disposed to cover an entirety of the piezoelectric portion 123a and a portion of an inclined portion 1231 of the piezoelectric layer 123. Accordingly, the second electrode (125a in FIG. 4) disposed in the extension portion E may be formed to have a smaller area than an inclined surface of the inclined portion 1231, and the second electrode 125 in the resonator 120 may be formed to have a smaller area than the piezoelectric layer 123.

Accordingly, as shown in FIG. 2, in a cross-section of the resonator 120 cut so as to cross the central portion S, an end of the second electrode 125 may be disposed in the extension portion E. Additionally, at least a portion of the end of the second electrode 125 disposed in the extension portion E may be disposed to overlap the insertion layer 170. Here, ‘overlap’ means that if the second electrode 125 was to be projected onto a plane on which the insertion layer 170 is disposed, a shape of the second electrode 125 projected onto the plane would overlap the insertion layer 170.

The second electrode 125 may be implemented as any one of an input electrode and an output electrode for inputting and outputting an electrical signal such as a radio frequency (RF) signal, or the like. That is, when the first electrode 121 is used as the input electrode, the second electrode 125 may be used as the output electrode, and when the first electrode 121 is used as the output electrode, the second electrode 125 may be used as the input electrode.

Meanwhile, as illustrated in FIG. 4, when the end of the second electrode 125 is positioned on the inclined portion 1231 of the piezoelectric layer 123 to be described later, since a local structure of acoustic impedance of the resonator 120 is formed in a sparse/dense/sparse/dense structure from the central portion S, a reflective interface reflecting a lateral wave inwardly of the resonator 120 is increased. Therefore, since most lateral waves could not flow outwardly of the resonator 120, and are reflected and then flow to an interior of the resonator 120, the performance of the acoustic resonator may be improved.

The piezoelectric layer 123 is a portion that converts electrical energy into mechanical energy in a form of elastic waves through a piezoelectric effect, and may be formed on the first electrode 121 and the insertion layer 170 to be described later.

As a material of the piezoelectric layer 123, zinc oxide (ZnO), aluminum nitride (AlN), doped aluminum nitride, lead zirconate titanate, quartz, and the like can be selectively used. In the case of doped aluminum nitride, a rare earth metal, a transition metal, or an alkaline earth metal may be further included. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). In addition, the alkaline earth metal may include magnesium (Mg).

In order to improve piezoelectric properties, when a content of elements doped with aluminum nitride (AlN) is lower than 0.1 at %, a piezoelectric property higher than that of aluminum nitride (AlN) cannot be realized. When the content of the elements exceeds 30 at %, it is difficult to fabricate and control the composition for deposition, such that uneven crystalline phases may be formed.

Therefore, in the example, the content of elements doped with aluminum nitride (AlN) may be in a range of 0.1 to 30 at %.

In the example, the piezoelectric layer is doped with scandium (Sc) in aluminum nitride (AlN). In this example, a piezoelectric constant may be increased to increase Kₜ² of the acoustic resonator.

The piezoelectric layer 123 according to the example may include a piezoelectric portion 123a disposed in the central portion S and a curved portion 123b disposed in the extension portion E.

The piezoelectric portion 123a is a portion that is directly stacked on the upper surface of the first electrode 121. Therefore, the piezoelectric portion 123a is interposed between the first electrode 121 and the second electrode 125 to be formed to have a flat shape, together with the first electrode 121 and the second electrode 125.

The curved portion 123b may be defined as a region extending from the piezoelectric portion 123a externally and positioned in the extension portion E.

The curved portion 123b is disposed on the insertion layer 170 to be described later, and is formed in a shape in which the upper surface thereof is raised or elevated along the shape of the insertion layer 170. Accordingly, the piezoelectric layer 123 is curved at a boundary between the piezoelectric portion 123a and the curved portion 123b, and the curved portion 123b is raised or elevated corresponding to the thickness and shape of the insertion layer 170.

The curved portion 123b may be divided into an inclined portion 1231 and an extension portion 1232.

The inclined portion 1231 means a portion formed to be inclined along an inclined surface L of the insertion layer 170 to be described later. The extension portion 1232 means a portion extending from the inclined portion 1231 externally.

In an example, the inclined portion 1231 may be formed parallel to the inclined surface L of the insertion layer 170, and an inclination angle of the inclined portion 1231 may be formed to be the same as an inclination angle of the inclined surface L of the insertion layer 170.

The insertion layer 170 is disposed along a surface formed by the membrane layer 150, the first electrode 121, and the etch stop portion 145. Therefore, the insertion layer 170 is partially disposed in the resonator 120, and is disposed between the first electrode 121 and the piezoelectric layer 123.

The insertion layer 170 may be disposed at a periphery of the central portion S to support the curved portion 123b of the piezoelectric layer 123. Accordingly, the curved portion 123b of the piezoelectric layer 123 may be divided into an inclined portion 1231 and an extension portion 1232 according to the shape of the insertion layer 170.

In the examples, the insertion layer 170 may be disposed in a region except for the central portion S. In an example, the insertion layer 170 may be disposed on the substrate 110 in an entire region except for the central portion S, or in different regions.

The insertion layer 170 may be formed to have a thickness that increases as a distance from the central portion S increases. Thereby, the insertion layer 170 may be formed of an inclined surface L that has a constant inclination angle 6 of the side surface disposed adjacent to the central portion S.

When the inclination angle 6 of the side surface of the insertion layer 170 is formed to be smaller than 5°, with regard to the manufacturing process, since the thickness of the insertion layer 170 should be formed to be very thin, or an area of the inclined surface L should be formed to be excessively large, it is practically difficult to be implemented.

Additionally, when the inclination angle θ of the side surface of the insertion layer 170 is formed to be greater than 70°, the inclination angle of the piezoelectric layer 123 or the second electrode 125 stacked on the insertion layer 170 may also be formed to be greater than 70°. In this example, since the piezoelectric layer 123 or the second electrode 125 stacked on the inclined surface L is excessively curved, cracks may be generated in the curved portion.

Therefore, in the example, the inclination angle θ of the inclined surface L is formed in a range of 5° or higher and 70° or lower.

In an example, the inclined portion 1231 of the piezoelectric layer 123 may be formed along the inclined surface L of the insertion layer 170, and thus may be formed at the same inclination angle as the inclined surface L of the insertion layer 170. Therefore, the inclination angle of the inclined portion 1231 is also formed in a range of 5° or higher and 70° or lower, similarly to the inclined surface L of the insertion layer 170. The configuration may also be equally applied to the second electrode 125 stacked on the inclined surface L of the insertion layer 170.

The insertion layer 170 may be formed of a material containing silicon (Si), oxygen (O), and nitrogen (N). In an example, the insertion layer 170 may be formed of a SiOxNy thin film in which nitrogen (N) is injected into the SiO₂ thin film.

The SiOxNy thin film may be formed by inserting a small amount of nitrogen into the SiO₂ thin film using N₂ gas or N₂O gas when the insertion layer 170 is formed of silicon dioxide (SiO₂).

The resonator 120 may be disposed to be spaced apart from the substrate 110 through a cavity C formed as an empty space.

The cavity C may be formed by removing a portion of the sacrificial layer 140 by supplying etching gas (or an etching solution to an inlet hole (H in FIG. 1) during a manufacturing process of the acoustic-wave resonator.

The protective layer 160 may be disposed along the surface of the acoustic-wave resonator 100 to protect the acoustic-wave resonator 100 from external elements. The protective layer 160 may be disposed along a surface formed by the second electrode 125, and the curved portion 123b of the piezoelectric layer 123.

In an example, the first electrode 121 and the second electrode 125 may extend externally of the resonator 120. A first metal layer 180 and a second metal layer 190 may be disposed on an upper surface of the extended portion, respectively.

The first metal layer 180 and the second metal layer 190 may be formed of, but not limited to, any one material of gold (Au), a gold-tin (Au—Sn) alloy, copper (Cu), a copper-tin (Cu—Sn) alloy, and aluminum (Al), and an aluminum alloy. Here, the aluminum alloy may be an aluminum-germanium (Al—Ge) alloy or an aluminum-scandium (Al—Sc) alloy.

The first metal layer 180 and the second metal layer 190 may serve to a connection wiring electrically connecting the electrodes 121 and 125 of the acoustic-wave resonator according to the example on the substrate 110, and the electrodes of other acoustic-wave resonators disposed adjacent to each other.

The first metal layer 180 may penetrate through the protective layer 160, and may be bonded to the first electrode 121.

Additionally, in the resonator 120, the first electrode 121 may be formed to have a larger area than the second electrode 125, and a first metal layer 180 may be formed on a circumferential portion of the first electrode 121.

Therefore, the first metal layer 180 may be disposed at the periphery of the resonator 120, and accordingly, may be disposed to surround the second electrode 125. However, the examples are not limited thereto.

Additionally, the protective layer 160 located on the resonator 120 may be disposed such that at least a portion of the protective layer 160 is in contact with the first metal layer 180 and the second metal layer 190. The first metal layer 180 and the second metal layer 190 are formed of a metal material having high thermal conductivity, and have a large volume, so that heat dissipation effect is high.

Therefore, the protective 160 is connected to the first metal layer 180 and the second metal layer 190 so that heat generated from the piezoelectric layer 123 may be quickly transferred to the first metal layer 180 and the second metal layer 190 via the protective layer 160.

In this example, at least a portion of the protective layer 160 may be disposed below an upper surface of the first and second metal layers 180 and 190. Specifically, the protective layer 160 may be interposed between the first metal layer 180 and the piezoelectric layer 123, and between the second metal layer 190 and the second electrode 125, and the piezoelectric layer 123, respectively.

In the bulk-acoustic wave resonator 100 according to the example configured as described above, a first electrode 121, a piezoelectric layer 123, and a second electrode 125 may be sequentially stacked to form a resonator 120. Additionally, an operation of forming the resonator 120 may include an operation of placing an insertion layer 170 below the first electrode 121 or between the first electrode 121 and the piezoelectric layer 123.

Therefore, the insertion layer 170 may be stacked on the first electrode 121, or the first electrode 121 may be stacked on the insertion layer 170.

In this example, the piezoelectric layer 123 and the second electrode 125 may be partially raised or elevated along the shape of the insertion layer 170, and the insertion layer 180 may be formed of a material containing silicon (Si), oxygen (O), and nitrogen (N).

In the bulk-wave acoustic resonator 100 according to the example, the insertion layer 170 may be formed of a SiOxNy thin film. In this example, in order to pattern the insertion layer 170 in the manufacturing process, a photomask pattern formed on the insertion layer 170 may be formed more precisely, so that a degree of precision of the insertion layer 170 may be improved. This will be described in more detail as follows.

After forming the insertion layer 170 to cover the entire surface formed by the membrane layer 150, the first electrode 121, and the etch stop portion 145, the insertion layer 170 of the bulk-acoustic wave resonator 100 according to the example may be completed by removing unnecessary portions disposed in the region corresponding to the central portion S.

In this example, as a method of removing the unnecessary portion, a photolithography method using a photoresist may be used. In this example, the insertion layer 170 may also be elaborately formed only when a photoresist serving as a mask is elaborately formed.

When the insertion layer 170 is formed of silicon dioxide (SiO₂), hydroxyl groups may be easily adsorbed on the surface or the inside of the insertion layer 170.Therefore, if a process (hereinafter, reworking process) such as a process of removing the initially applied photoresist and reapplying the photoresist, or the like, is performed, the re-applied photoresist may not be elaborately formed due to the hydroxyl groups adsorbed on the SiO₂ insertion layer.

It is noted that there may be a variation between the critical dimension of the initially formed photoresist and the critical dimension of the reworked photoresist, when the insertion layer 170 made of a silicon dioxide (SiO₂) material is formed and then a photoresist applied thereon, and a necessary pattern is repeatedly is formed through an exposure/development process.

Additionally, when the insertion layer is formed of a SiOxNy material and a photoresist is formed thereon, the variation between the critical dimension of the initially formed photoresist and the critical dimension of the reworked photoresist may be minimized.

In an example, the insertion layer may be subject to deposition through a plasma-enhanced CVD (PECVD) method. However, the configuration of the example is not limited thereto, and various chemical vapor deposition (CVD) methods such as, but not limited to, low-pressure (CVD), atmosphere pressure (APCVD), or the like, may be implemented.

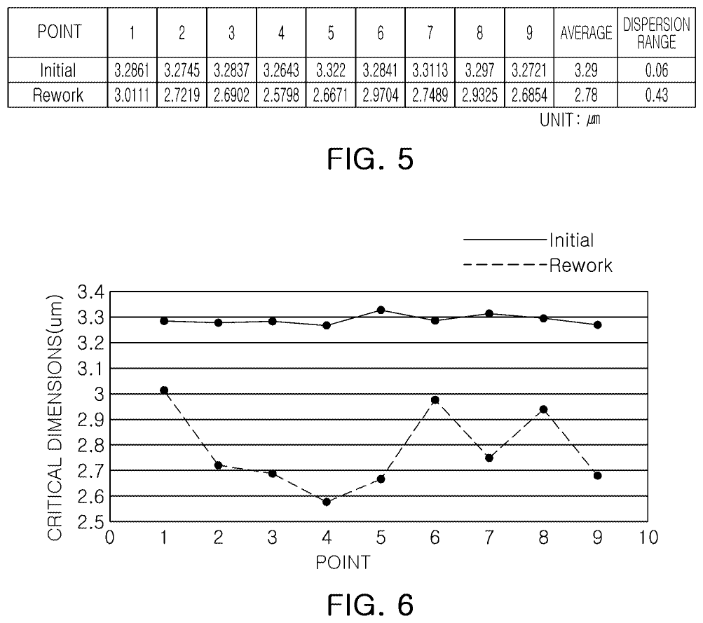

FIGS. 5 and 6 are diagrams illustrating the critical dimensions of the bulk-wave acoustic resonator, in which the insertion layer is formed of silicon dioxide, FIG. 5 is a table illustrating values obtained by measuring critical dimensions at nine points (1 to 9 points) on a wafer, and FIG. 6 is a graph illustrating the critical dimensions of FIG. 5 in a graph.

Here, 1 to 9 points refer to 9 points separated spaced apart in a grid shape on the wafer.

Here, the measured value in FIG. 5 is a value obtained by measuring critical dimensions (CD) of a photoresist by forming an insertion layer by depositing silicon dioxide (SiO₂) with a thickness of 3000 Å at a deposition temperature of 300° C. by a plasma enhanced CVD (PFCVD) method, and forming the photoresist thereon. Here, the critical dimension of the photoresist may be measured using critical dimensions measurement scanning microscope (CD-SEM).

In this example, the insertion layer made of silicon dioxide (SiO₂) may be formed through Equation 1 below.

SiH₄+O₂→SiO₂+2H₂ Equation 1:

Referring to FIGS. 5 and 6, an average of the critical dimensions of the photoresist applied at an initial stage may be 3.29 um and a dispersion range may be 0.06 um. However, when reworking is performed, an average of the critical dimensions of the photoresist may be 2.78 um and the dispersion range may be 0.43 um.

Accordingly, it can be seen that when the insertion layer is formed of silicon dioxide (SiO₂), the dispersion of the critical dimensions of the re-applied photoresist is significantly increased compared to the dispersion of the critical dimensions of the first applied photoresist.

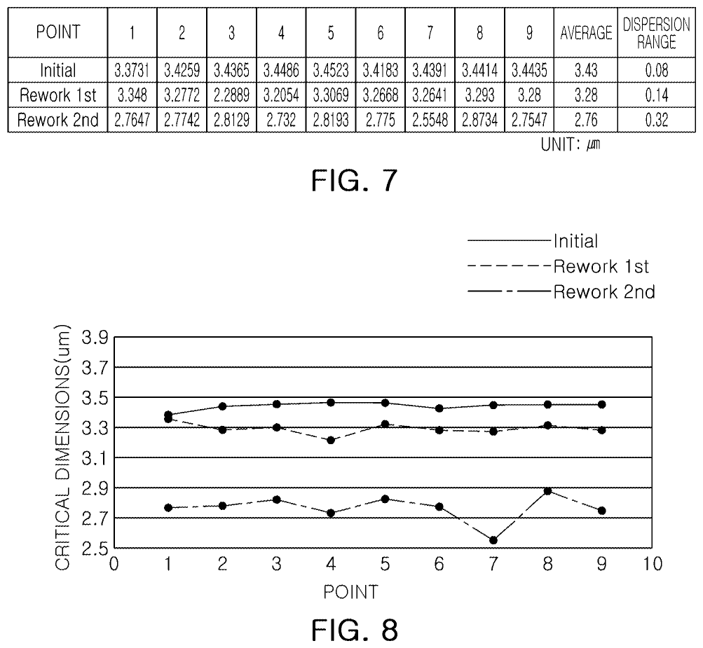

FIGS. 7 and 8 illustrate examples in which only the deposition temperature is increased under the same environment as illustrated in FIGS. 5 and 6, and FIG. 7 is a table illustrating values obtained by measuring critical dimension at nine points on a wafer, and FIG. 8 is a view illustrating the critical dimension of FIG. 7 in a graph.

In an example, a measured value in FIG. 7 is a value obtained by measuring critical dimensions by forming an insertion layer made of a silicon dioxide (SiO₂) material by being deposited to a thickness of 3000 Å at 400° C. by a PECVD method, and forming a photoresist thereon. The insertion layer of this embodiment may be formed through Equation 1 described above.

Referring to FIGS. 7 and 8, an average of critical dimensions of the photoresist applied at an initial stage may be 3.43 μm and a dispersion range may be 0.08 μm, which were good. However, when a first reworking process (“Rework 1^{st}” process) is performed, the average of the critical dimensions of the photoresist may be increased to 3.28 μm, and the dispersion range may be increased to 0.14 μm. When a second reworking process (“Rework 2^{nd}” process) is performed, the average of the critical dimensions of the photoresist may be 2.76 μm, and the dispersion range may be 0.32 μm, which were increased further than the first reworking process.

Accordingly, it can be seen that when the deposition temperature is increased from 300° C. to 400° C. without changing the material of the insertion layer, the dispersion may not increase significantly in the first reworking process, but the dispersion increases significantly in the second reworking process.

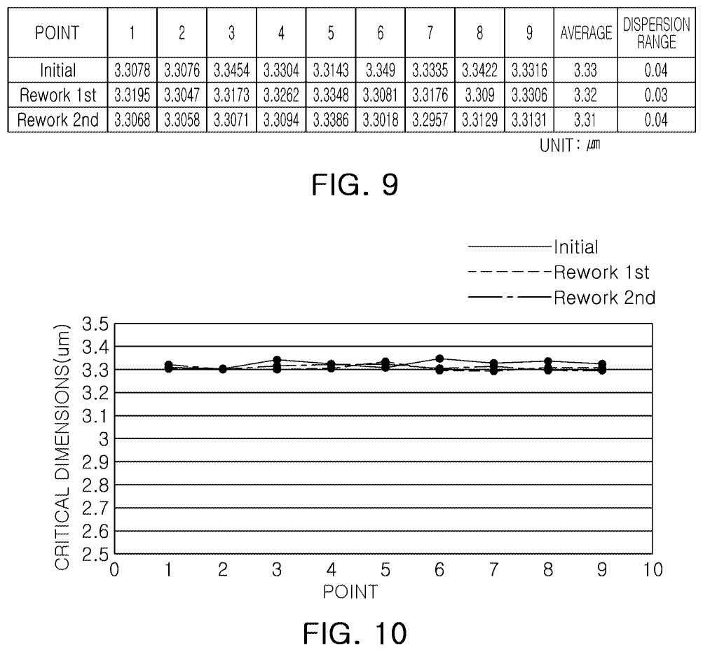

FIGS. 9 and 10 are views illustrating critical dimensions of a bulk-wave acoustic resonator, in which an insertion layer is formed of a SiOxNy material, FIG. 9 is a table illustrating critical dimensions measured at each of nine points on a wafer, and FIG. 10 is a view illustrating the critical dimension of FIG. 9 in a graph.

Here, the measured value of FIG. 9 is a value obtained by measuring critical dimensions by depositing an insertion layer to a thickness of 3000 Å at 300° C. by a PECVD method, mixing SiH₄and N₂O in an appropriate ratio to form an insertion layer made of a SiOxNy material, and forming a photoresist thereon.

The insertion layer made of the SiOxNy material may be formed through Equation 2 below.

SiH₄+N₂O→H₂ Equation 2:

Referring to FIGS. 9 and 10, the average of the critical dimensions of the photoresist applied at the initial stage may be 3.33 um and the dispersion range may be 0.04um, which were good, and when the first reworking process (“Rework 1^{st}” process) is performed, the average of the critical dimension of the photoresist may be 3.32 um, and the dispersion range may be 0.03um, which were measured not to be significantly changed compared to the initial period.

Additionally, when the second reworking process (“Rework 2^{nd}” process) is performed, the average of the critical dimensions of the photoresist may be 3.31 um and the dispersion range may be 0.04 um. Accordingly, there may not be a significant change compared to the initial stage.

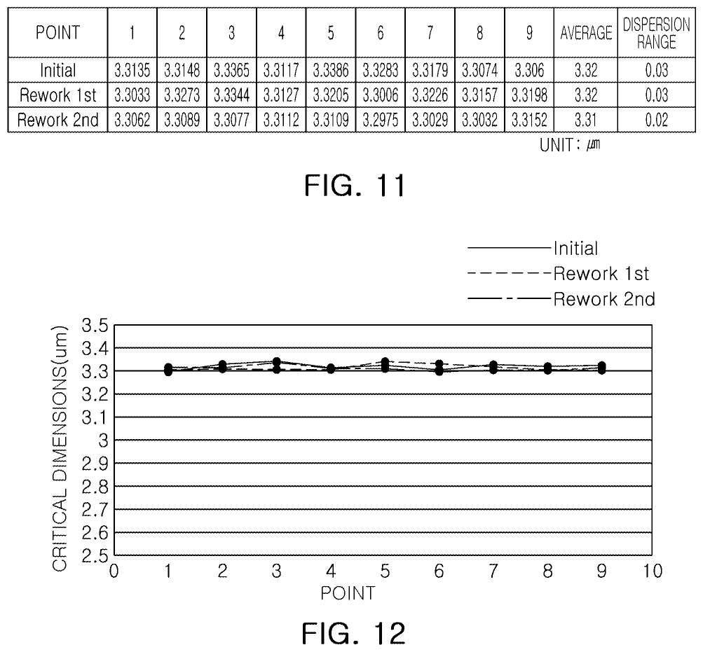

FIGS. 11 and 12 are diagrams illustrating the critical dimensions of the bulk-acoustic wave resonator, in which the insertion layer is formed of a SiOxNy material, FIG. 11 is a table illustrating values measured at each of nine points on the wafer, and FIG. 12 is a diagram illustrating the critical dimension of 11 in a graph.

In an example, the measured value of FIG. 11 is a value that is obtained by performing deposition of an insertion layer at a thickness of 3000 Å at 400° C. by a PECVD method, mixing SiH₄ and N₂O at an appropriate ratio to form an insertion layer made of a SiOxNy material, and forming a photoresist thereon to measure critical dimensions. Therefore, the insertion layer can be formed through Equation 2 above.

Referring to FIGS. 11 and 12, the average of the critical dimensions of the photoresist applied at the initial stage may be 3.32 um and the dispersion range may be 0.03 um, which were good. However, when the first reworking process (“Rework 1^{st}” process) is performed, the average of the critical dimensions may be 3.32 um, and the dispersion range may be 0.03 um, which were measured not to be significantly changed from the initial period.

Additionally, when the second reworking process (“Rework 2^{nd}” process) is performed, the average of the critical dimensions of the photoresist may be 3.31 um and the dispersion range may be 0.02 um. Accordingly, there may not be a significant change compared to the initial stage.

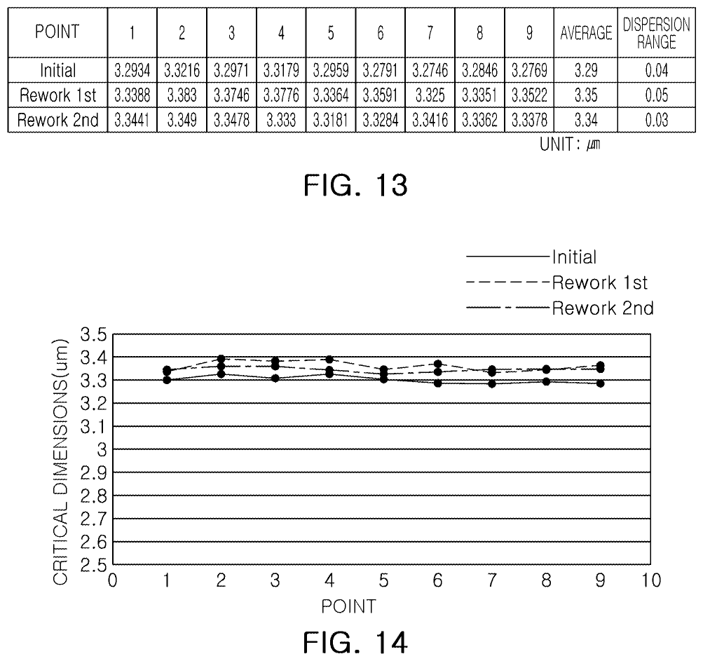

FIGS. 13 and 14 are diagrams illustrating critical dimensions of a bulk-acoustic wave resonator, in which an insertion layer is formed of SiOxNy material, FIG. 13 is a table illustrating values measured at each of nine points on a wafer, and FIG. 14 is a diagram illustrating the critical dimension of 13 in a graph.

In an example, the measured value in FIG. 13 is a value obtained by performing deposition of an insertion layer at a thickness of 3000 Å at 300° C. by a PECVD method, mixing SiH₄, O₂, and N₂ gas at an appropriate ratio to form an insertion layer made of a SiOxNy material, and forming a photoresist thereon to measure critical dimensions.

The insertion layer made of SiOxNy can be formed through Equation 3 below.

SiH₄+O₂+N₂→H₂ Equation 3:

The average of the critical dimension of the initial photoresist may be 3.29 um and the dispersion range may be 0.04 um, and when the first reworking process (“Rework 1^{st}” process) is performed, the average of the critical dimensions of the photoresist may be 3.35 um, and the dispersion range may be 0.05 um. Accordingly, there was no significant change compared to the initial period.

Additionally, when the second reworking process (“Rework 2^{nd}” process) is performed, the average of the critical dimensions of the photoresist may be 3.34 um and the dispersion range may be 0.03 um. Accordingly, there was still no significant change compared to the initial stage.

In an example, the insertion layer 170, made of the SiOxNy material, may have a different dispersion range depending on the content of nitrogen (N).

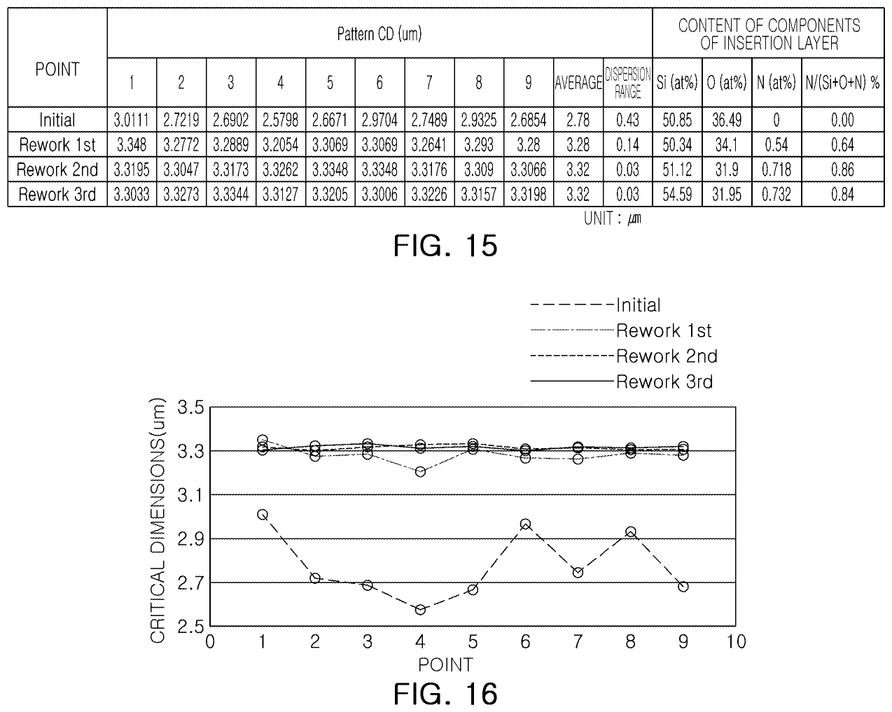

FIGS. 15 and 16 are views illustrating the critical dimensions and the content of each element of the bulk-acoustic wave resonator formed with an insertion layer made of a SiOxNy material, FIG. 15 is a table illustrating values obtained by measuring critical dimensions at nine points on a wafer, and FIG. 16 is a graph illustrating the critical dimensions of FIG. 15.

Referring to FIGS. 15 and 16, it can be seen that a dispersion range of the SiOxNy thin film in this example may vary according to the content of nitrogen (N).

In this example, a content ratio of nitrogen (N) to the SiOxNy thin film may be defined through Equation 4 below.

Content ratio of nitrogen (N)=(at % of nitrogen (N))/(at % of silicon (Si)+at % of oxygen (O)+at % of nitrogen (N)). Equation 4:

As a result of measuring the dispersion range by varying the content ratio of nitrogen (N) as shown in FIG. 15, the content ratio of nitrogen (N) may be 0.86% or higher, even if the photoresist is repeatedly formed, the dispersion range may be maintained at 0.03 μm, so that a pattern of the photoresist can be stably implemented.

Accordingly, in the insertion layer of this example, the at % content of nitrogen (N) in the SiOxNy thin film may be 0.86% or higher of the at % content of the entire insertion layer 170.

Additionally, since the insertion layer 170 is used for a reflective structure of a horizontal wave of a bulk-acoustic wave resonator, it may be formed of a material having low acoustic impedance. Therefore, it is advantageous to use a material having properties similar to SiO₂, which has typically been used as a material for the insertion layer 170.

When the nitrogen content in the SiOxNy thin film is greater than the nitrogen content of oxygen, the characteristics of the insertion layer 170 may be closer to the characteristics of Si₃N₄ than the characteristics of SiO₂. In this example, the horizontal wave reflective characteristics of the bulk-acoustic wave resonator may be deteriorated.

Referring to FIG. 4, in the example of the bulk-acoustic wave, since the acoustic impedance of the resonator 120 has a local structure formed in a sparse/dense/sparse/dense structure from the central portion S, a plurality of reflective interfaces for reflecting horizontal waves into the resonator 120 are provided.

Acoustic impedance is an inherent property of a material and is expressed as a product of a density of a material in a bulk state (kg/m³) and a speed of sound waves in the material (m/s). Additionally, in this example, the discussion that the reflection characteristic of the acoustic resonator is large means that a loss generated as a lateral wave escapes to the outside of the resonator 120 is small, and consequently, the performance of the acoustic resonator is improved.

In order to increase the reflective characteristics of the horizontal wave at each reflective interface, it is advantageous to configure the insertion layer 170 of a material having a large difference in acoustic impedance from the piezoelectric layer 123 and the electrodes 121 and 125. The acoustic impedance of SiO₂ is 12.96 kg/ m²s and that of Si₃N₄ is 35.20 kg/ m²s. Additionally, AlN used as a material of the piezoelectric layer 123 has acoustic impedance of 35.86 kg/ m²s, and molybdenum (Mo) used as a material of the first electrode has acoustic impedance of 55.51 kg/ m²s.

When the nitrogen content in the SiOxNy thin film is greater than oxygen, a Si₃N₄ reaction occurs rapidly, and the insertion layer 170 exhibits characteristics close to that of the Si₃N₄ material. In this example, since the acoustic impedance of the insertion layer 170 is similar to the acoustic impedance of the piezoelectric layer 123, reflective characteristics thereof are deteriorated. On the contrary, when the oxygen content in the SiOxNy thin film is greater than nitrogen and the characteristics of the insertion layer 170 become close to the SiO₂ characteristics, since the acoustic impedance of the insertion layer 170 is significantly different from the acoustic impedance of the piezoelectric layer 123, reflective characteristics thereof are improved.

Therefore, in order to form the insertion layer 170 of the piezoelectric layer 123 or a material having a large difference in acoustic impedance from the first electrode, it is advantageous to form the insertion layer 170 of SiOxNy rather than Si₃N₄.

Accordingly, in the examples, the insertion layer 170 is formed of a SiOxNy thin film, and nitrogen is contained in the SiOxNy thin film in at %, lower than that of oxygen. Through this configuration, it is possible to secure the horizontal wave reflective characteristics of the bulk-acoustic wave resonator and at the same time, improve the degree of precision of the insertion layer 170.

In an example, the content analysis of each element in the SiOxNy thin film can be confirmed by an energy dispersive X-ray spectroscopy (EDS) analysis of a scanning electron microscopy (SEM) and a transmission electron microscope (TEM), but is not limited thereto, and it is also possible to use an X-ray photoelectron spectroscopy (XPS) analysis, or the like.

As described above, in the bulk-acoustic wave resonator according to the present embodiment, the insertion layer 170 is formed of a SiOxNy material. Accordingly, even if the photoresist formed on the insertion layer 170 is repeatedly re-coated to pattern the insertion layer 170, a dispersion of the critical dimension does not increase.

Therefore, even if the photoresist is repeatedly re-applied in the manufacturing process of the insertion layer 170, the photoresist and the insertion layer 170 can be precisely and stably formed, so that manufacturing is easy and energy leakage of the bulk-acoustic wave resonator can be minimized.

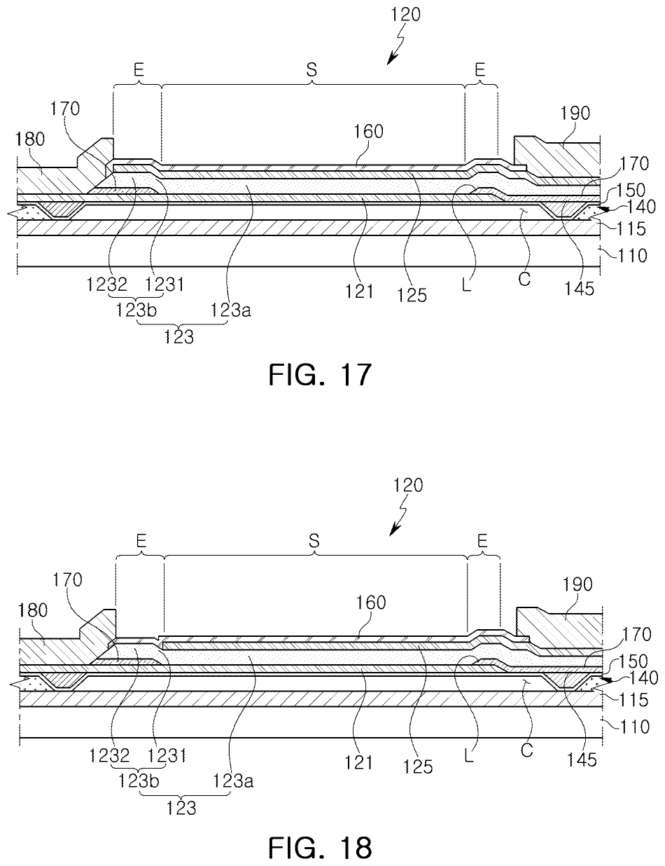

FIG. 17 is a schematic cross-sectional view of a bulk-acoustic wave resonator, in accordance with one or more embodiments.

In the bulk-acoustic wave resonator illustrated in this example, a second electrode 125 is disposed on an entire upper surface of the piezoelectric layer 123 in the resonator 120, and accordingly, the second electrode 125 is formed not only on the inclined portion 1231 but also on the extension portion 1232 of the piezoelectric layer 123.

FIG. 18 is a schematic cross-sectional view of a bulk-acoustic wave resonator, in accordance with one or more embodiments.

Referring to FIG. 18, in the bulk-acoustic wave resonator according to the present example, in a cross-section of the resonator 120 cut to across the central portion S, an end portion of the second electrode 125 may be formed only on an upper surface of the piezoelectric portion 123a of the piezoelectric layer 123, and may not be formed on the curved portion 123b. Accordingly, the end of the second electrode 125 is disposed along a boundary between the piezoelectric portion 123a and the inclined portion 1231.

As described above, the bulk-acoustic wave resonator according to the present disclosure can be modified in various forms as necessary.

As set forth above, according to the bulk-acoustic wave resonator according to the present disclosure, since an insertion layer is formed of a SiOxNy material, even if a photoresist formed on the insertion layer is repeatedly re-applied to pattern the insertion layer, the insertion layer may be precisely and stably formed. Therefore, it is easy to manufacture and it is possible to minimize the energy leakage of the bulk-acoustic wave resonator.

While this disclosure includes specific examples, it will be apparent after an understanding of the disclosure of this application that various changes in forms and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

1. A bulk-acoustic wave resonator, comprising:
a resonator, comprising a first electrode, a piezoelectric layer, and a second electrode sequentially stacked on a substrate; and
an insertion layer, disposed below the piezoelectric layer, and configured to partially elevate the piezoelectric layer and the second electrode,
wherein the insertion layer is formed of a material containing silicon (Si), oxygen (O), and nitrogen (N).

2. The bulk-acoustic wave resonator of claim 1, wherein an at % content of the nitrogen (N) contained in the insertion layer is 0.86% or higher than the at % content of the entire insertion layer, and is lower than an at % content of oxygen (O).

3. The bulk-acoustic wave resonator of claim 1, wherein the piezoelectric layer is formed of one of aluminum nitride (AlN) and scandium (Sc) doped aluminum nitride.

4. The bulk-acoustic wave resonator of claim 1, wherein the first electrode is formed of molybdenum (Mo).

5. The bulk-acoustic wave resonator of claim 1, wherein the insertion layer is formed of a material having an acoustic impedance lower than an acoustic impedance of the first electrode and the piezoelectric layer.

6. The bulk-acoustic wave resonator of claim 1, wherein the resonator comprises a central portion disposed in a central region, and an extension portion disposed at a periphery of the central portion,
the insertion layer is disposed in the extension portion of the resonator,
the insertion layer has an inclined surface of which a thickness increases as a distance from the central portion increases, and
the piezoelectric layer comprises an inclined portion disposed on the inclined surface of the insertion layer.

7. The bulk-acoustic wave resonator of claim 6, wherein, in a cross-section cut across the resonator, an end of the second electrode is disposed at a boundary between the central portion and the extension portion, or disposed on the inclined portion.

8. The bulk-acoustic wave resonator of claim 6, wherein the piezoelectric layer comprises a piezoelectric portion disposed in the central potion, and an extension portion extending outwardly of the inclined portion, and
at least a portion of the second electrode is disposed on the extension portion of the piezoelectric layer.

9. A bulk-acoustic wave resonator manufacturing method, the method comprising:
forming a resonator, in which a first electrode, a piezoelectric layer, and a second electrode are sequentially stacked,
wherein the forming of the resonator comprises forming an insertion layer below the first electrode, or forming the insertion layer between the first electrode and the piezoelectric layer to partially elevate the piezoelectric layer and the second electrode, and
wherein the insertion layer is formed of a material containing silicon (Si), oxygen (O), and nitrogen (N).

10. The method of claim 9, wherein an at % content of the nitrogen (N) contained in the insertion layer is 0.86% or higher than the at % content of the entire insertion layer and is lower than an at % content of oxygen (O).

11. The method of claim 9, wherein the insertion layer is formed by mixing SiH₄, and N₂O gases in a predetermined ratio.

12. The method of claim 11, wherein the insertion layer is formed by a chemical vapor deposition (CVD) method, and by applying the following equation:
SiH₄+N₂O→SiOₓN_{y}+H₂.

13. The method of claim 9, wherein the insertion layer is formed by mixing SiH₄, O₂, and N₂ gases in a predetermined ratio.

14. The method of claim 13, wherein the insertion layer is formed by a chemical vapor deposition (CVD) method, and following by applying the following equation:
SiH₄+O₂+N₂→SiOₓN_{y}+H₂.

15. The method of claim 9, wherein the insertion layer is formed of one of aluminum nitride (AlN) and scandium (Sc) doped aluminum nitride.

16. The method of claim 9, wherein the insertion layer is formed of a material having an acoustic impedance that is lower than an acoustic impedance of the first electrode and the piezoelectric layer.

17. A bulk-acoustic wave resonator, comprising:
a substrate;
a resonator, comprising:
a central portion including a first electrode, a piezoelectric layer, and a second electrode sequentially stacked on the substrate, and
an extension portion, extending from the central portion, and including an insertion layer disposed between the first electrode and the piezoelectric layer;
wherein the insertion layer is formed of a silicon dioxide (SiO₂) thin film.

18. The bulk-acoustic wave resonator of claim 17, wherein nitrogen (N) is injected into the SiO₂ thin film.
